(19) United States
(12) Patent Application Publication
(10) Pub. No.: US 2025/0172393 A1
(43) Pub. Date: May 29, 2025

(54) Vibrator Device And Method For Manufacturing Vibrator Device

(71) Applicant: SEIKO EPSON CORPORATION, Tokyo (JP)

(72) Inventor: Seiichiro OGURA, Minowa (JP)

(21) Appl. No.: 18/961,559

(22) Filed: Nov. 27, 2024

(30) Foreign Application Priority Data
Nov. 28, 2023 (JP) 2023-200473

(51) Int. Cl. G01C 19/5783; G01C 25/00

(52) U.S. Cl. CPC G01C 19/5783; G01C 25/00

(57) ABSTRACT

Provided is a vibrator device including a support substrate and a vibrator element. The support substrate includes a frame section. The vibrator element is disposed on the support substrate and includes a base portion. The support substrate includes a first beam and a second beam. The first beam and the second beam are made of the same material as the frame section. The first beam extends from the frame section and includes a first tip in a portion where the first beam overlaps the base portion. The second beam extends from the frame section and includes a second tip in a portion where the second beam overlaps the base portion. The base portion and the first tip are connected to each other with a first bonding member disposed therebetween. The base portion and the second tip are connected to each other with a second bonding member disposed therebetween.

The present application is based on, and claims priority from JP Application Serial Number 2023-200473, filed Nov. 28, 2023, the disclosure of which is hereby incorporated by reference herein in its entirety.

### BACKGROUND

### 1. Technical Field

The present disclosure relates to a vibrator device and a method for manufacturing a vibrator device.

### 2. Related Art

A gyro sensor disclosed in JP-A-2017-26336 includes a gyro element and a support that supports the gyro element. The gyro element includes drive arms that detect the angular rate. A vibrator device disclosed in JP-A-2021-32841 includes a vibrator element, a support substrate, and a circuit element. Specifically, a base portion of the vibrator element is attached to an element holder at a center portion of the support substrate with bonding members disposed between the base portion and the element holder.

However, in the arrangement known in the art, it is less likely to reduce deformation of the base portion or strain on the base portion, which is caused under vibration of the drive arms, resulting in degradation of vibration characteristics.

### SUMMARY

A vibrator device includes a support substrate and a vibrator element. The support substrate includes a frame section. The vibrator element is disposed on the support substrate and includes a base portion. The support substrate includes a first beam and a second beam that are made of the same material as the frame section. The first beam extends from the frame section and includes a first tip in a portion where the first beam overlaps the base portion. The second beam extends from the frame section and includes a second tip in a portion where the second beam overlaps the base portion. The base portion and the first tip are connected to each other with a first bonding member disposed therebetween. The base portion and the second tip are connected to each other with a second bonding member disposed therebetween.

A method for manufacturing a vibrator device is provided. The vibrator device includes a support substrate and a vibrator element. The support substrate includes a frame section. The vibrator element is disposed on the support substrate and includes a base portion. The support substrate includes a first beam and a second beam that are made of the same material as the frame section. The first beam extends from the frame section and includes a first tip in a portion where the first beam overlaps the base portion. The second beam extends from the frame section and includes a second tip in a portion where the second beam overlaps the base portion. The base portion and the first tip are connected to each other with a first bonding member disposed therebetween. The base portion and the second tip are connected to each other with a second bonding member disposed therebetween. The method includes forming the frame section, the first beam, and the second beam all at once.

### BRIEF DESCRIPTION OF THE DRAWINGS

FIG. 1 is a sectional view illustrating a configuration of a vibrator device.

FIG. 2 is a plan view illustrating the configuration of the vibrator device.

FIG. 3 is a plan view illustrating a configuration of a vibrator element.

FIG. 4 is a sectional view of the vibrator element taken along line IV-IV in FIG. 3.

FIG. 5 is a sectional view of the vibrator element taken along line V-V in FIG. 3.

FIG. 6 schematically illustrates a state in which the vibrator element is driven.

FIG. 7 schematically illustrates a state in which the vibrator element is driven.

FIG. 8 is a plan view illustrating a configuration of a support substrate.

FIG. 9 is a flowchart of a method for manufacturing the vibrator device.

FIG. 10 is a plan view illustrating a configuration of a support substrate according to a variation.

FIG. 11 is a plan view illustrating a configuration of a support substrate according to a variation.

### DESCRIPTION OF EMBODIMENTS

A, B, and C in each drawing denote three axes orthogonal to one another. The direction of the A-axis, the direction of the B-axis, and the direction of the C-axis are hereinafter referred to as an “A direction”, a “B direction”, and a “C direction”, respectively. The direction indicated by each arrow represents a plus direction, and the opposite direction thereof represents a minus direction. The C-axis is an imaginary axis extending in the vertical direction. The +C direction points to an upper side, and the −C direction points to a lower side. The −C direction is the direction of gravity. Plan view in the thickness direction of a support substrate 500, that is, in the direction of the C-axis may be hereinafter also simply referred to as plan view.

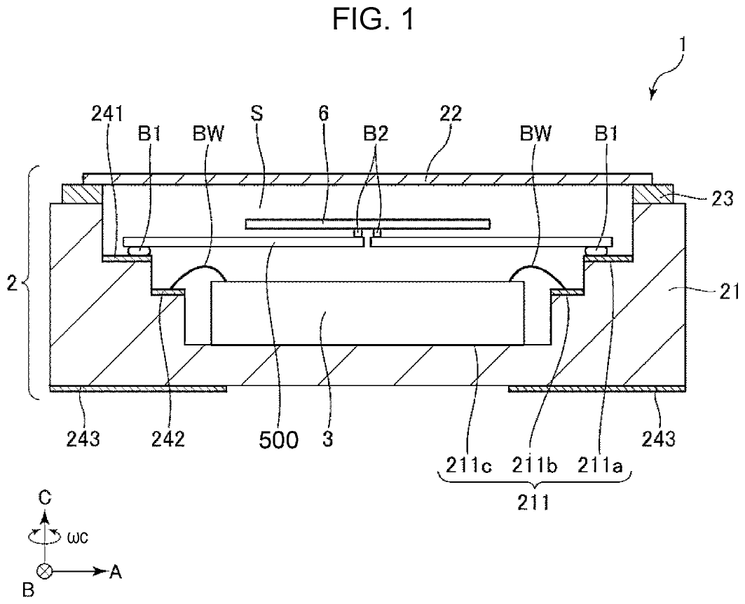

The configuration of a vibrator device 1 is described below with reference to FIGS. 1 to 5.

Referring to FIG. 1, the vibrator device 1 is a physical quantity sensor that detects the angular rate ωc about its detection axis (the C-axis). The vibrator device 1 serving as a physical quantity sensor can be incorporated into a wide variety of electronic apparatuses. The vibrator device 1 can thus be a convenient-to-use device with increasing demand. Examples of the physical quantity sensor include gyro sensors. A vibrator device including a double T-shaped gyro element is described below as an example of the vibrator device 1.

The vibrator device 1 includes a package 2, a circuit element 3, a support substrate 500, and a vibrator element 6. The circuit element 3, the support substrate 500, and the vibrator element 6 are housed in the package 2.

The package 2 includes a base 21 and a lid 22. The base 21 has a recess 211 having an opening in an upper surface of the base 21. The lid 22 is bonded to the upper surface of the base 21 with a bonding member 23 disposed therebetween. The opening of the recess 211 is closed with the lid 22. The recess 211 defines an internal space S within the package 2. The circuit element 3, the support substrate 500, the vibrator element 6 are disposed in the internal space S.

The base 21 may be made of, for example, a ceramic material, such as alumina. The lid 22 may be made of a metal material, such as Kovar. The base 21 and the lid 22 may be made of other materials.

The internal space S is airtight. The internal space S is under a reduced pressure and is preferably close to a vacuum. This reduces viscous drag and improves the vibration characteristics of the vibrator element 6. However, the atmosphere of the internal space S is not limited to a particular atmosphere. For example, the internal space S may be at the atmospheric pressure or may be pressurized.

The recess 211 consists of multiple recessed sections that are denoted by 211a, 211b, and 211c. The recessed section 211a has the opening in the upper surface of the base 21. The recessed section 211b has an opening at the bottom of the recessed section 211a. The opening width of the recessed section 211b is less than the opening width of the recessed section 211a. The recessed section 211c has an opening at the bottom of the recessed section 211b. The opening width of the recessed section 211c is less than the opening width of the recessed section 211b. The support substrate 500 is fixed to the bottom of the recessed section 211a, with the vibrator element 6 supported by the support substrate 500. The circuit element 3 is fixed to the bottom of the recessed section 211c.

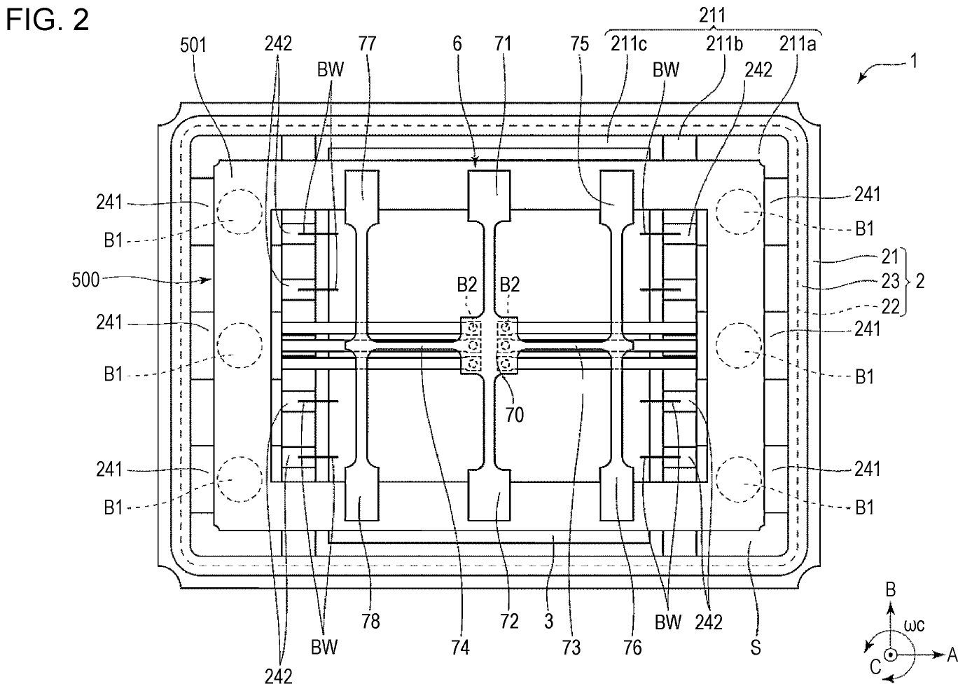

As illustrated in FIG. 2, the vibrator element 6, the support substrate 500, and the circuit element 3 overlap each other in the internal space S in plan view. In other words, the vibrator element 6, the support substrate 500, and the circuit element 3 are arranged along the C-axis. This enables the vibrator device 1 to be reduced in size without an increase in the dimension of the package 2 along a plane extending in the A-axis and B-axis directions. The support substrate 500 is located between the vibrator element 6 and the circuit element 3 and supports the vibrator element 6 from below, that is, from the minus side of the C-axis.

As illustrated in FIGS. 1 and 2, internal terminals 241 are disposed at the bottom of the recessed section 211a. Likewise, internal terminals 242 are disposed at the bottom of the recessed section 211b. External terminals 243 are disposed on a lower surface of the base 21. Wiring (not illustrated) in the base 21 provides electrical connection for the internal terminals 241, the internal terminals 242, and the external terminals 243.

The internal terminals 241 are electrically connected to the vibrator element 6 through bonding members B1, bonding members B2, and the support substrate 500. The bonding members B1 and B2 are electrically conductive. The internal terminals 242 are electrically connected to the circuit element 3 through bonding wires BW.

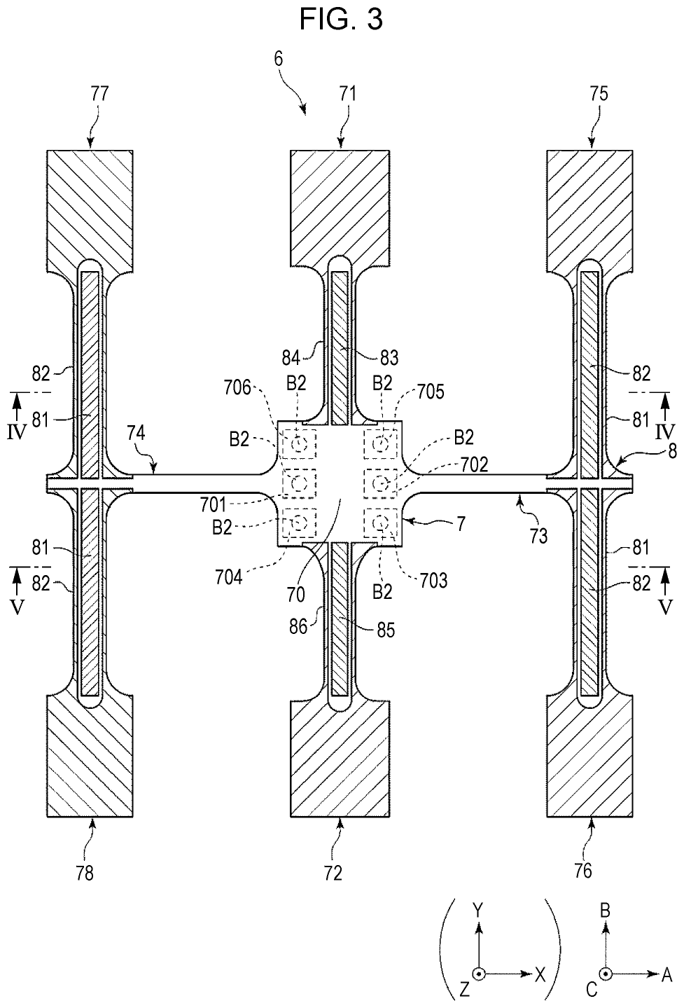

The vibrator element 6 is a physical quantity sensor element or, more specifically, an angular rate sensor element capable of detecting the angular rate ωc about its detection axis (the C-axis). As illustrated in FIG. 3, the vibrator element 6 includes a vibrator substrate 7 and an electrode 8, which is disposed on a surface of the vibrator substrate 7. The vibrator substrate 7 is a Z-cut quartz crystal substrate. The Z-cut quartz crystal substrate extends along an XY-plane defined by crystal axes, that is, by the X-axis (the electrical axis of quartz crystal) and the Y-axis (the mechanical axis of quartz crystal). The thickness direction of the Z-cut quartz crystal substrate is the direction of the Z-axis (the optical axis of quartz crystal).

The vibrator substrate 7 includes a base portion 70, a detection arm 71, a detection arm 72, a linking arm 73, a linking arm 74, a drive arm 75, a drive arm 76, a drive arm 77, and a drive arm 78. The base portion 70 is located at a center portion of the vibrator substrate 7. The detection arms 71 and 72 are a pair of arms extending from the base portion 70 toward the opposite sides in the B-axis direction. The linking arms 73 and 74 are a pair of arms extending from the base portion 70 toward the opposite sides in the A-axis direction. The drive arms 75 and 76 are a pair of arms extending from the tip of the linking arm 73 toward the opposite sides in the B-axis direction. The drive arms 77 and 78 are a pair of arms extending from the tip of the linking arm 74 toward the opposite sides in the B-axis direction. The vibrator substrate 7 has the shape as described above so that the vibrator element 6 can vibrate in a well-balanced manner.

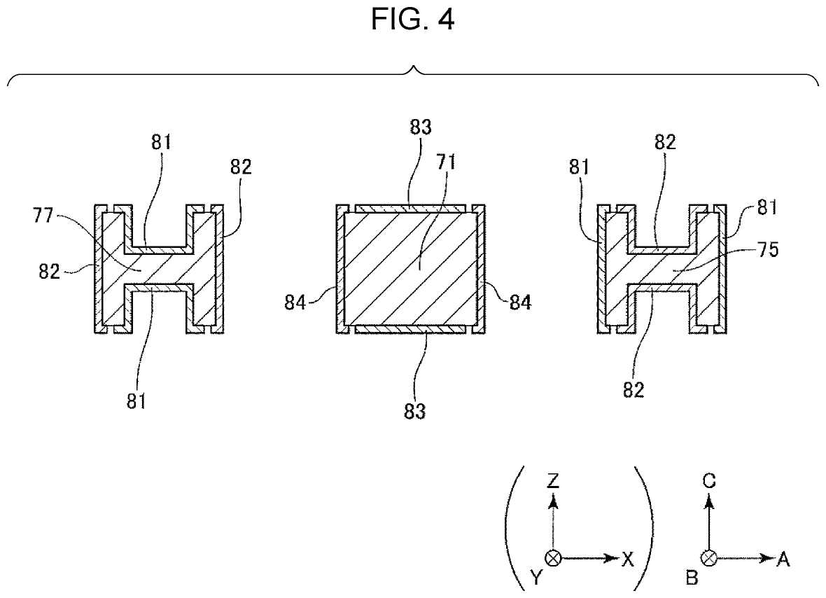

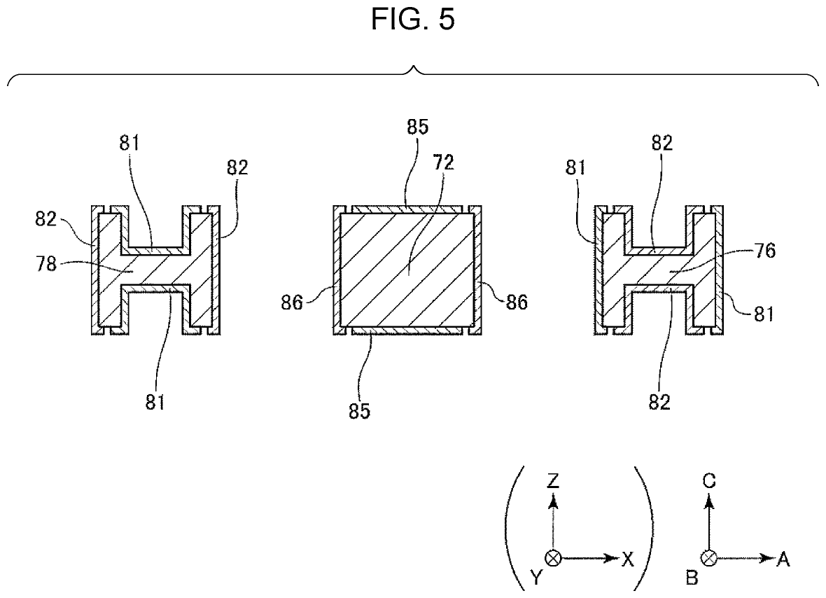

As illustrated in FIGS. 4 and 5, the drive arms 75 to 78 each have grooves having openings in upper and lower surfaces thereof and are thus substantially H-shaped in cross section. Likewise, the detection arms 71 and 72 may each have grooves having openings in upper and lower surfaces thereof and may be substantially H-shaped in cross section.

As illustrated in FIG. 3, the electrode 8 includes driving signal electrodes 81, driving ground electrodes 82, first detection signal electrodes 83, first detection ground electrodes 84, second detection signal electrodes 85, and second detection ground electrodes 86.

The driving signal electrodes 81 are disposed on opposite side surfaces of each of the drive arms 75 and 76 and on upper and lower surfaces of each of the drive arms 77 and 78. The driving ground electrodes 82 are disposed on upper and lower surfaces of each of the drive arms 75 and 76 and on opposite side surfaces of each of the drive arms 77 and 78.

The first detection signal electrodes 83 are disposed on upper and lower surfaces of the detection arm 71. The first detection ground electrodes 84 are disposed on opposite side surfaces of the detection arm 71. The second detection signal electrodes 85 are disposed on upper and lower surfaces of the detection arm 72. The second detection ground electrodes 86 are disposed on opposite side surfaces of the detection arm 72.

The electrodes 81 to 86 are each routed to a lower surface of the base portion 70. As illustrated in FIG. 3, terminals denoted by 701 to 706 are disposed on the lower surface of the base portion 70. The terminal 701 is electrically connected to the driving signal electrodes 81. The terminal 702 is electrically connected to the driving ground electrodes 82. The terminal 703 is electrically connected to the first detection signal electrodes 83. The terminal 704 is electrically connected to the first detection ground electrodes 84. The terminal 705 is electrically connected to the second detection signal electrodes 85. The terminal 706 is electrically connected to the second detection ground electrodes 86.

As illustrated in FIG. 1, the circuit element 3 is fixed to the bottom of the recessed section 211c. The circuit element 3 includes a drive circuit and a detection circuit to drive the vibrator element 6 and to detect the angular rate ωc applied to the vibrator element 6. Examples of the circuit element 3 are not limited to the one mentioned above. For example, the circuit element 3 may include a temperature compensation circuit or any other circuit.

As illustrated in FIG. 1, the support substrate 500 is located between the base 21 and the vibrator element 6. The support substrate 500 serves mainly the purpose of absorbing or relieving stress caused by deformation of the base 21, thus keeping the stress from being transferred to the vibrator element 6.

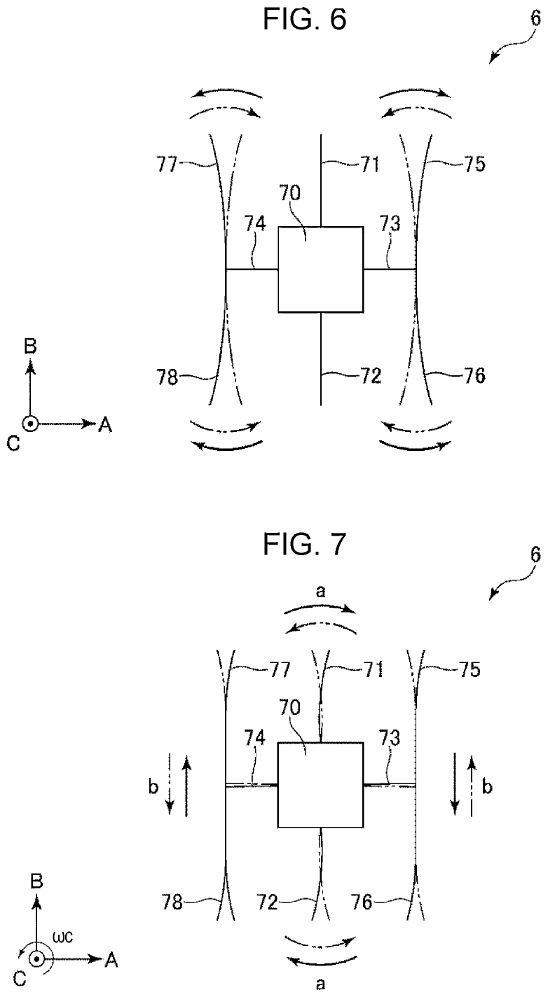

The process of detecting the angular rate ωc with the vibrator element 6 is described below with reference to FIGS. 6 and 7.

As illustrated in FIG. 6, when a driving signal is applied between the driving signal electrodes 81 and the driving ground electrodes 82, the drive arms 75 to 78 produce flexural vibration. The driving mode concerned is hereinafter referred to as a driving vibration mode.

When the angular rate ωc is applied to the vibrator element 6 being driven in the driving vibration mode, another mode or, more specifically, a detection vibration mode is activated, as illustrated in FIG. 7. Upon activation of the detection vibration mode, the Coriolis force acts on the drive arms 75 to 78, which in turn vibrate in the direction of arrows b. Then, flexural vibration is produced by the detection arms 71 and 72 in response to the vibration in the direction mentioned above; that is, detection vibration is produced in the direction of arrows a.

The detection arms 71 and 72 in the detection vibration mode carry electric charge, which is then extracted as first and second detection signals. The first detection signal is extracted from between the first detection signal electrodes 83 and the first detection ground electrodes 84 of the detection arm 71. The second detection signal is extracted from between the second detection signal electrodes 85 and the second detection ground electrodes 86 of the detection arm 72. The angular rate ωc can be detected based on the first and second detection signals.

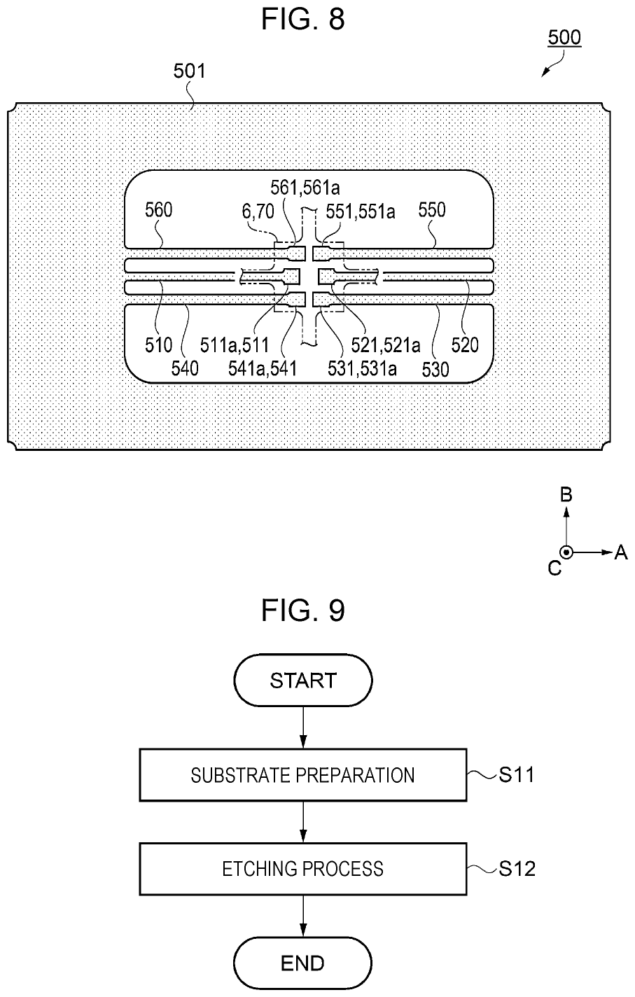

The following describes the configuration of the support substrate 500 with reference to FIG. 8.

The support substrate 500 includes a frame section 501, a first beam 510, and a second beam 520 in plan view in the direction of the C-axis. The frame section 501 is a frame fixed to the base 21. The frame section 501 is rectangular in shape. The first beam 510 is a first extension portion extending from the frame section 501 in the +A direction. The second beam 520 extends from the frame section 501 in the −A direction.

The support substrate 500 includes a third beam 530 and a fourth beam 540. The third beam 530 extends from the frame section 501 in the −A direction, and the fourth beam 540 extends from the frame section 501 in the +A direction. The support substrate 500 includes a fifth beam 550 and a sixth beam 560. The fifth beam 550 extends from the frame section 501 in the −A direction, and the sixth beam 560 extends from the frame section 501 in the +A direction. The first beam 510 to the sixth beam 560 are not in contact with one another and are discretely located away from one another.

The first beam 510 has a first tip 511 in a portion where the first beam 510 overlaps the base portion 70 of the vibrator element 6 in plan view. The second beam 520 has a second tip 521 in a portion where the second beam 520 overlaps the base portion 70 of the vibrator element 6 in plan view. The third beam 530 has a third tip 531 in a portion where the third beam 530 overlaps the base portion 70 of the vibrator element 6 in plan view. The fourth beam 540 has a fourth tip 541 in a portion where the fourth beam 540 overlaps the base portion 70 of the vibrator element 6 in plan view. The fifth beam 550 has a fifth tip 551 in a portion where the fifth beam 550 overlaps the base portion 70 of the vibrator element 6 in plan view. The sixth beam 560 has a sixth tip 561 in a portion where the sixth beam 560 overlaps the base portion 70 of the vibrator element 6 in plan view.

The first beam 510 to the sixth beam 560 are made of the same material as the frame section 501. For example, the frame section 501 is made of quartz crystal. The frame section 501 may be made of a material other than quartz crystal and may, for example, be made of silicon.

As described above, since the frame section 501 and the first beam 510 to the sixth beam 560 of the support substrate 500 are made of the same material, that is, quartz crystal, the thermal expansion coefficient of the frame section 501 is equal to the thermal expansion coefficient of each of the first beam 510 to the sixth beam 560. Thus, substantially no thermal stress due to differences in thermal expansion coefficient occurs, and stress is likely to be reduced.

The first beam 510 and the second beam 520 are preferably made of the same material as the vibrator element 6. That is, the support substrate 500 is preferably made of the same material as the vibrator element 6. When the vibrator element 6 and the support substrate 500 are made of the same material, effects of the thermal expansion coefficient can be reduced even if the temperature changes in the vibrator element 6 and the support substrate 500. This can reduce the possibility that the vibration characteristics will degrade.

The cut angle of the quartz crystal substrate used as the support substrate 500 is equal to the cut angle of the quartz crystal substrate used as the vibrator substrate 7 included in the vibrator element 6. The direction of each crystal axis of the support substrate 500 coincides with the direction of the corresponding crystal axis of the vibrator substrate 7. That is, the X-, Y-, and Z-axes of the support substrate 500 coincide with the X-, Y-, and Z-axes, respectively, of the vibrator substrate 7.

Quartz crystal has different thermal expansion coefficients for different axial directions, namely, the directions of the X-, Y-, and Z-axes. Accordingly, when the cut angle of the support substrate 500 is equal to the cut angle of the vibrator substrate 7 and the direction of each crystal axis of the support substrate 500 coincides with the direction of the corresponding crystal axis of the vibrator substrate 7, the possibility that thermal stress will be generated between the support substrate 500 and the vibrator substrate 7 is further reduced. As a result, stress to the vibrator element 6 is more likely to be reduced. This can more effectively reduce the possibility that the vibration characteristics of the vibrator element 6 will degrade or change.

Examples of the support substrate 500 are not limited to the one mentioned above. For example, when the support substrate 500 and the vibrator substrate 7 are quartz crystal substrates with the same cut angle, the direction of each crystal axis of the support substrate 500 may be different from the direction of the corresponding crystal axis of the vibrator substrate 7. The support substrate 500 and the vibrator substrate 7 may be quartz crystal substrates with different cut angles.

As illustrated in FIGS. 1 to 3, the support substrate 500 is electrically connected to the base portion 70 of the vibrator element 6 through the conductive bonding members B2.

Specifically, the first tip 511 of the first beam 510 of the support substrate 500 is electrically connected to the base portion 70 through a first bonding member B2. The second tip 521 of the second beam 520 of the support substrate 500 is electrically connected to the base portion 70 through a second bonding member B2. Likewise, the third tip 531 to the sixth tip 561 are electrically connected to the base portion 70 through the respective bonding members B2. The support substrate 500 is fixed to the bottom of the recessed section 211a with the conductive bonding members B1 disposed therebetween.

As mentioned above, the first beam 510, the second beam 520, and the like extend from the frame section 501 of the support substrate 500. The first beam 510 is connected to the base portion 70 with the first bonding member B2 disposed therebetween. The second beam 520 is connected to the base portion 70 with the second bonding member B2 disposed therebetween. Accordingly, when the vibrator element 6 vibrates, the first beam 510 and the second beam 520 individually undergo flexible deformation to absorb, relieve, or reduce the strain on the base portion 70. The same holds true for the third beam 530 to the sixth beam 560. This enables the vibrator device 1 to be provided in which the vibration characteristics of the vibrator element 6 are less likely to degrade.

The support substrate 500 is disposed between the vibrator element 6 and the base 21, in which case the support substrate 500 can absorb or relieve stress transferred from the base 21 and can thus reduce the stress being transferred to the vibrator element 6. This can effectively reduce the possibility that the vibration characteristics of the vibrator element 6 will degrade or change.

The material of the bonding members B1 and B2 is not limited to a particular material as long as the bonding members B1 and B2 are electrically conductive and can provide a bond between two components. Examples of the bonding members B1 and B2 include various kinds of metal bumps, such as gold bumps, silver bumps, copper bumps, and solder bumps; and conductive adhesives, such as polyimide-based adhesives, epoxy-based adhesives, silicone-based adhesives, and acrylic-based adhesives, containing a silver filler or any other conductive filler dispersed therein.

When the bonding members B1 and B2 are metal bumps, gas is less generated from the bonding members B1 and B2. Using metal bumps as the bonding member B1 and B2 can thus effectively reduce the possibility of environmental changes, especially pressure rise, in the internal space S. When the bonding members B1 and B2 are conductive adhesives, the bonding members B1 and B2 are relatively soft and can therefore absorb or relieve stress.

The first tip 511 and the second tip 521 include a wide portion 511a and a wide portion 521a, respectively, which are wider than the other part of each of the first beam 510 and the second beam 520. Likewise, the third tip 531 to the sixth tip 561 include a wide portion 531a, a wide portion 541a, a wide portion 551a, and a wide portion 561a, respectively. Since the wide portions 511a to 561a are provided, the first bonding member B2, the second bonding member B2, and the like are less likely to protrude beyond the first beam 510 and the second beam 520. It is thus ensured that the first beam 510 and the second beam 520 are electrically connected to the base portion 70.

The support substrate 500 has a wiring pattern (not illustrated) formed thereon to provide an electrical connection between the vibrator element 6 and the internal terminals 241. The wiring pattern is electrically connected to the internal terminals 241, each of which is provided for the corresponding one of the terminals 701 to 706.

The following describes a method for manufacturing the vibrator device 1, with reference to FIG. 9. As part of the method for manufacturing the vibrator device 1, a procedure for producing the support substrate 500 is mainly described below.

Referring to FIG. 9, a substrate that is to be used as the support substrate 500 is prepared in Step S11. Specifically, a quartz crystal substrate, for example, is prepared.

In Step S12, the quartz crystal substrate is subjected to an etching process. For example, a metal film is formed on the quartz crystal substrate by a deposition of a corrosion-resistant metal, such as gold or chromium. Subsequently, a resist pattern is formed on an upper surface of the metal film, which is then subjected to an etching process. The quartz crystal substrate is subjected to an etching process, in which the pattern on the etched metal film is used as an etching mask. As a result, the support substrate 500 is obtained and includes the frame section 501, the first beam 510 extending from the frame section 501, and the second beam 520 extending from the frame section 501.

The third beam 530 to the sixth beam 560 are also formed in the aforementioned manner. That is, the frame section 501 and the first beam 510 to the sixth beam 560, which are made of the same material, are formed all at once. Subsequently, the first bonding member B2 is disposed to form an electrical connection between the first tip 511 of the first beam 510 and the base portion 70. Likewise, the second bonding member B2 is disposed to form an electrical connection between the second tip 521 of the second beam 520 and the base portion 70. This completes the manufacturing of the vibrator device 1.

As described above, since the frame section 501, the first beam 510, and the second beam 520 are formed all at once, the first beam 510 and the second beam 520 extend from the frame section 501 of the support substrate 500. Thus, the first beam 510 is connected to the base portion 70 with the first bonding member B2 disposed therebetween and the second beam 520 is connected to the base portion 70 with the second bonding member B2 disposed therebetween. Accordingly, when the vibrator element 6 vibrates, the first beam 510 and the second beam 520 individually undergo flexible deformation to absorb, relieve, or reduce the strain on the base portion 70. This leads to the manufacturing of the vibrator device 1 in which the vibration characteristics of the vibrator element 6 are less likely to degrade.

As described above, the vibrator device 1 according to the present embodiment includes the support substrate 500 and the vibrator element 6. The support substrate 500 includes the frame section 501. The vibrator element 6 is disposed on the support substrate 500 and includes the base portion 70. The support substrate 500 includes the first beam 510 and the second beam 520. The first beam 510 and the second beam 520 are made of the same material as the frame section 501. The first beam 510 extends from the frame section 501 and includes the first tip 511 in a portion where the first beam 510 overlaps the base portion 70. The second beam 520 extends from the frame section 501 and includes the second tip 521 in a portion where the second beam 520 overlaps the base portion 70. The base portion 70 and the first tip 511 are connected to each other with the first bonding member B2 disposed therebetween. The base portion 70 and the second tip 521 are connected to each other with the second bonding member B2 disposed therebetween.

With this configuration, the first beam 510 and the second beam 520 extend from the frame section 501 of the support substrate 500, the first beam 510 is connected to the base portion 70 with the first bonding member B2 disposed therebetween, and the second beam 520 is connected to the base portion 70 with the second bonding member B2 disposed therebetween. Accordingly, when the vibrator element 6 vibrates, the first beam 510 and the second beam 520 individually undergo flexible deformation to absorb, relieve, or reduce the strain on the base portion 70. Thus, the vibrator device 1 is provided in which the vibration characteristics of the vibrator element 6 are less likely to degrade.

Wiring is formed on the individual beams 510 to 560 via the bonding members B2. This simplifies the process of installing wiring on the support substrate 500. The support substrate 500 and the beams 510 to 560 can reduce the possibility that a misalignment will be produced between the support substrate 500 and the beams 510 to 560 as compared to the configuration in which the support substrate 500 is different from a substrate in which the beams 510 to 560 are disposed. The vibrator device 1 with reduced performance variation is obtained accordingly.

With regard to the vibrator device 1 according to the present embodiment, the vibrator element 6, the first beam 510, and the second beam 520 are preferably made of the same material. When the vibrator element 6, the first beam 510, and the second beam 520 are made of the same material, effects of the thermal expansion coefficient can be reduced even if the temperature changes in the vibrator element 6, the first beam 510, and the second beam 520. This can reduce the possibility that the vibration characteristics will degrade.

With regard to the vibrator device 1 according to the present embodiment, at least one of the first tip 511 and the second tip 521 preferably includes a wide portion (511a, 521a) that is wider than the other part of each of the first beam 510 and the second beam 520. Since the wide portions 511a and 521a are provided, the first bonding member B2 and the second bonding member B2 are less likely to protrude beyond the first beam 510 and the second beam 520. It is thus ensured that the first beam 510 and the second beam 520 are electrically connected to the base portion 70.

The vibrator device 1 according to the present embodiment preferably includes the circuit element 3 electrically coupled to the vibrator element 6. With this configuration, the vibrator device 1 includes the circuit element 3 and can be used as a gyro sensor or an oscillator.

The vibrator device 1 according to the present embodiment preferably includes the package 2, and the support substrate 500 and the vibrator element 6 are preferably disposed in the package 2. With this configuration, the vibrator element 6 is housed in the package 2 together with other components so that the vibrator element 6 is sealed airtight. This can reduce the possibility that the vibration characteristics will degrade.

A method for manufacturing a vibrator device according to the present embodiment is a method for manufacturing the vibrator device 1 including the support substrate 500 and the vibrator element 6. The support substrate 500 includes the frame section 501. The vibrator element 6 is disposed on the support substrate 500 and includes the base portion 70. The support substrate 500 includes the first beam 510 and the second beam 520. The first beam 510 and the second beam 520 are made of the same material as the frame section 501. The first beam 510 extends from the frame section 501 and includes the first tip 511 in a portion where the first beam 510 overlaps the base portion 70. The second beam 520 extends from the frame section 501 and includes the second tip 521 in a portion where the second beam 520 overlaps the base portion 70. The base portion 70 and the first tip 511 are connected to each other with the first bonding member B2 disposed therebetween. The base portion 70 and the second tip 521 are connected to each other with the second bonding member B2 disposed therebetween. The method includes forming the frame section 501, the first beam 510, and the second beam 520 all at once.

The method includes forming the frame section 501, the first beam 510, and the second beam 520 all at once so that the first beam 510 and the second beam 520 extend from the frame section 501 of the support substrate 500. The first beam 510 is connected to the base portion 70 with the first bonding member B2 disposed therebetween. The second beam 520 is connected to the base portion 70 with the second bonding member B2 disposed therebetween. When the vibrator element 6 vibrates, the first beam 510 and the second beam 520 individually undergo flexible deformation to absorb, relieve, or reduce the strain on the base portion 70. Thus, the method for manufacturing the vibrator device 1 is provided in which the vibration characteristics of the vibrator element 6 are less likely to degrade.

The following describes variations of the embodiment above.

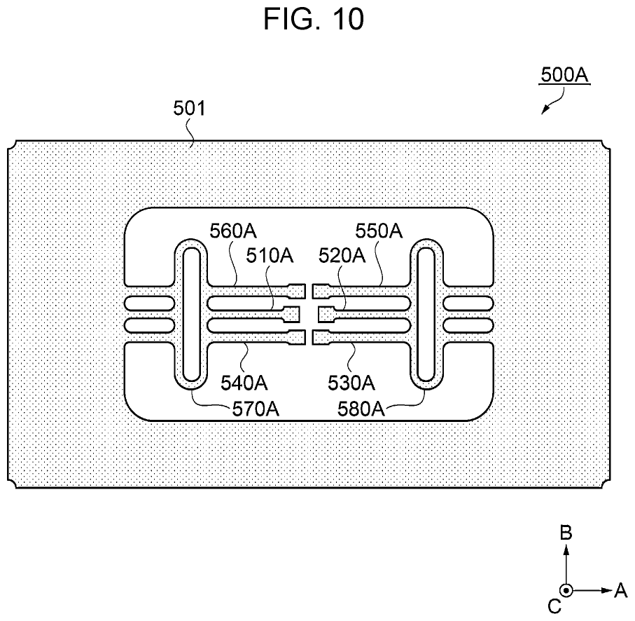

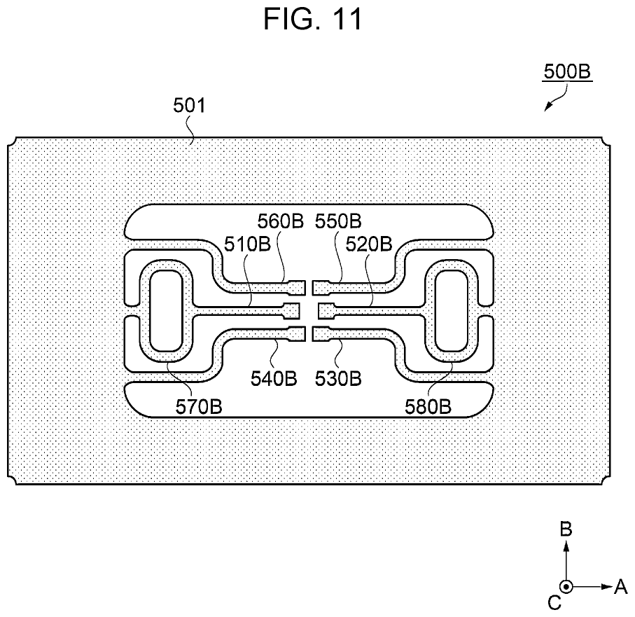

As described above, the support substrate 500 includes the first beam 510 extending from the frame section 501 in the +A direction and the second beam 520 extending from the frame section 501 in the −A direction. The support substrate is not limited thereto. A support substrate 500A, which is illustrated in FIG. 10, may serve as an alternative.

As illustrated in FIG. 10, the support substrate 500A according to a variation may include portions extending in a second extension direction (i.e., the +B direction and the −B direction) while the first beam 510 and the second beam 520 extend in a first extension direction (i.e., the +A direction and the −A direction).

Specifically, a first beam 510A, a fourth beam 540A, and a sixth beam 560A extend from the frame section 501 in the +A direction and include a flat spring portion 570A, which is located between two ends of the respective beams and extends in the +B direction and the −B direction. Likewise, a second beam 520A, a third beam 530A, and a fifth beam 550A extend from the frame section 501 in the −A direction and include a flat spring portion 580A, which is located between two ends of the respective beams and extends in the +B direction and the −B direction.

That is, at least one of the first beam 510A and the second beam 520A of the support substrate 500A described above according to the variation includes a first extension portion (the beam 510, the beam 520) extending in the first extension direction and a second extension portion (570A, 580A) extending in another direction, namely, the second extension direction. With this configuration, since the first extension portion and the second extension portion are included, the displacement caused by the strain imposed in the first extension direction (i.e., the +A direction and the −A direction) can be absorbed by the flat spring portions 570A and 580A. This can reduce the possibility that the vibration characteristics will degrade.

As described above, the support substrate 500 includes the first beam 510 extending from the frame section 501 in the +A direction and the second beam 520 extending from the frame section 501 in the −A direction. The support substrate is not limited thereto. A support substrate 500B, which is illustrated in FIG. 11, may serve as an alternative.

As illustrated in FIG. 11, the support substrate 500B according to a variation may extend in the second extension direction (i.e., the +B direction and the −B direction) while the first beam 510 and the second beam 520 extend in the first extension direction (i.e., the +A direction and the −A direction).

Specifically, a first beam 510B extends from the frame section 501 in the +A direction and includes a flat spring portion 570B, which is located between two ends of the beam and extends in the +B direction and the −B direction. A portion being part of a fourth beam 540B and located between two ends thereof extends in the +B direction. A portion being part of a sixth beam 560B and located between two ends thereof extends in the −B direction.

A second beam 520B extends from the frame section 501 in the −A direction and includes a flat spring portion 580B, which is located between two ends of the beam and extends in the +B direction and the −B direction. A portion being part of a third beam 530B and located between two ends thereof extends in the +B direction. A portion being part of a fifth beam 550B and located between two ends thereof extends in the −B direction.

In the support substrate 500B according to the variation described above, only the first beam 510B and the second beam 520B include the flat spring portions 570B and 580B, respectively. Thus, the flat spring portions 570B and 580B are less likely to be affected by the beams 530B, 540B, 550B, and 560B when there is a slight difference in motion between adjacent beams.

The flat spring portions 570B and 580B are provided to only the first beam 510B and the second beam 520B among the first beam 510b to the sixth beam 560B, because the first beam 510B and the second beam 520B are more prone to deformation than the other beams. Accordingly, displacement caused by the strain imposed in the +A direction and the −A direction can be absorbed. This can reduce the possibility that the vibration characteristics will degrade. The other beams, namely, the third beam 530B to the sixth beam 560B do not include flat spring portions so that the support substrate 500B can be reduced in size.

Examples of the vibrator element 6 are not limited to the double T-shaped gyro element mentioned above. The vibrator element 6 may be an H-shaped gyro sensor element or a silicon MEMS gyro sensor element. Instead of the vibrator element 6 being a gyro element, the vibrator element 6 may be, for example, a tuning fork vibrator element.

What is claimed is:

1. A vibrator device comprising:
a support substrate including a frame section; and
a vibrator element disposed on the support substrate and including a base portion,
the support substrate including a first beam and a second beam that are made of a same material as the frame section,
the first beam extending from the frame section and including a first tip in a portion where the first beam overlaps the base portion,
the second beam extending from the frame section and including a second tip in a portion where the second beam overlaps the base portion,
the base portion and the first tip being connected to each other with a first bonding member disposed therebetween,
the base portion and the second tip being connected to each other with a second bonding member disposed therebetween.

2. The vibrator device according to claim 1, wherein the vibrator element, the first beam, and the second beam are made of the same material.

3. The vibrator device according to claim 1, wherein at least one of the first beam and the second beam includes a first extension portion extending in a first extension direction and a second extension portion extending in a second extension direction different from the first extension direction.

4. The vibrator device according to claim 1, wherein at least one of the first tip and the second tip includes a wide portion wider than other part of each of the first beam and the second beam.

5. The vibrator device according to claim 1, further comprising a circuit element electrically coupled to the vibrator element.

6. The vibrator device according to claim 1, further comprising a package, the support substrate and the vibrator element being disposed in the package.

7. A method for manufacturing a vibrator device including a support substrate and a vibrator element,
the support substrate including a frame section,
the vibrator element being disposed on the support substrate and including a base portion,
the support substrate including a first beam and a second beam that are made of a same material as the frame section,
the first beam extending from the frame section and including a first tip in a portion where the first beam overlaps the base portion,
the second beam extending from the frame section and including a second tip in a portion where the second beam overlaps the base portion,
the base portion and the first tip being connected to each other with a first bonding member disposed therebetween,
the base portion and the second tip being connected to each other with a second bonding member disposed therebetween,
the method comprising forming the frame section, the first beam, and the second beam all at once.
